(19) United States
(12) Patent Application Publication
(10) Pub. No.: US 2019/0337068 A1
(43) Pub. Date: Nov. 7, 2019

(54) HIGH CURRENT BI-POLAR PULSE SYSTEM FOR USE IN ELECTROCHEMICAL METAL SURFACE FINISHING

(71) Applicant: JEFFERSON SCIENCE ASSOCIATES, LLC, Newport News, VA (US)

(72) Inventors: CHARLES REECE, YORKTOWN, VA (US); HUI TIAN, YORKTOWN, VA (US); JOHN MUSSON, NEWPORT NEWS, VA (US)

(21) Appl. No.: 16/402,159

(22) Filed: May 2, 2019

Related U.S. Application Data
(60) Provisional application No. 62/665,562, filed on May 2, 2018.

(51) Int. Cl. B23H 3/02; B23H 3/04; C25F 3/26; H01L 39/24; H05H 7/20

(52) U.S. Cl. CPC B23H 3/02; B23H 3/04; H05H 7/20; H01L 39/2406; C25F 3/26

(57) ABSTRACT

A high current bi-polar pulse system for use in electrochemical metal surface finishing of metallic components. The high current bi-polar pulse system provides a high isolation, high current switching device for providing independently controllable, alternating polarity, variable time duration pulses for electrochemical and mechanical finishing of metallic components in a conducting fluid bath. The high current bi-polar pulse system provides a safe, low-cost solution for implementing the surface finishing of niobium (Nb) SRF accelerating cavities without the use of hydrofluoric acid.

The United States Government may have certain rights to this invention under Management and Operating Contract No. DE-AC05-06OR23177 from the Department of Energy.

### FIELD OF THE INVENTION

The present invention relates to the production of niobium (Nb) superconducting radio frequency (SRF) cavities and more particularly to a system for facilitating economical surface finishing of Nb SRF accelerating cavities.

### BACKGROUND

Although the etching and electropolishing of niobium (Nb) superconducting radio frequency (SRF) cavities with hydrofluoric acid is well established, the procedure presents serious safety and environmental hazards and it is quite expensive. Hydrofluoric acid is of particular danger as it is both an extremely corrosive substance as well as a deadly contact poison, capable of being absorbed through the skin or eyes. As a result, electropolishing systems which incorporate hydrofluoric acid typically require substantial financial investments in infrastructure in order to provide for the safe use and, ultimately, disposal of the hazardous solution.

Due to the inherent hazards associated with the use of hydrofluoric acid, a more environmentally friendly, and less dangerous, method of polishing has been proposed which relies upon an electrolytic solution which is free of hydrofluoric acid and provides for the introduction of alternating anodic pukes and cathodic pulses into the cavity being polished. While this method is effective, it is desirable to increase the process rate associated with this method while minimizing equipment and other infrastructure costs. Although conventional rectifier-based pulse control systems for bipolar electropolishing (EP) have been proposed to increase the surface area covered and speed of polishing, they are generally costly.

Accordingly there is a need for a safe, reliable, and economical etching and electropolishing system for the production of Nb superconducting radio frequency (SRF) cavities.

### OBJECTS AND ADVANTAGES OF THE INVENTION

A first object of the invention is to provide a high current bi-polar pulse system for use in electrochemical metal surface finishing.

A second object is to provide a system for implementing a low-cost solution for the surface finishing of niobium (Nb) SRF accelerating cavities.

A further object of the invention is to provide a system for the surface finishing of niobium (Nb) SRF accelerating cavities that eliminates the use of hydrofluoric acid.

A further object is to provide a system for safely and reliably carrying out an electropolishing procedure on niobium (Nb) SRF accelerating cavities.

A still further object is to provide a system for producing surface-finished niobium (Nb) SRF accelerating cavities at a much lower unit cost than conventional rectifier-based pulse control systems.

These and other objects and advantages of the present invention will be understood by reading the following description along with reference to the drawings.

### SUMMARY OF THE INVENTION

The invention is a high current bi-polar pulse system for use in electrochemical metal surface finishing of metallic components. The high current bi-polar pulse system provides a high isolation, high current switching device for providing independently controllable, alternating polarity, variable time duration pulses for electrochemical and mechanical finishing of metallic components in a conducting fluid bath. The high current bi-polar pulse system provides a safe, low-cost solution for implementing the surface finishing of niobium (Nb) SRF accelerating cavities without the use of hydrofluoric acid.

### BRIEF DESCRIPTION OF THE SEVERAL VIEWS OF THE DRAWING(S)

Reference is made herein to the accompanying drawings, which are not necessarily drawn to scale, and wherein:

FIG. 1 is a schematic depicting the high isolation, high current switching device of the current invention.

### DETAILED DESCRIPTION

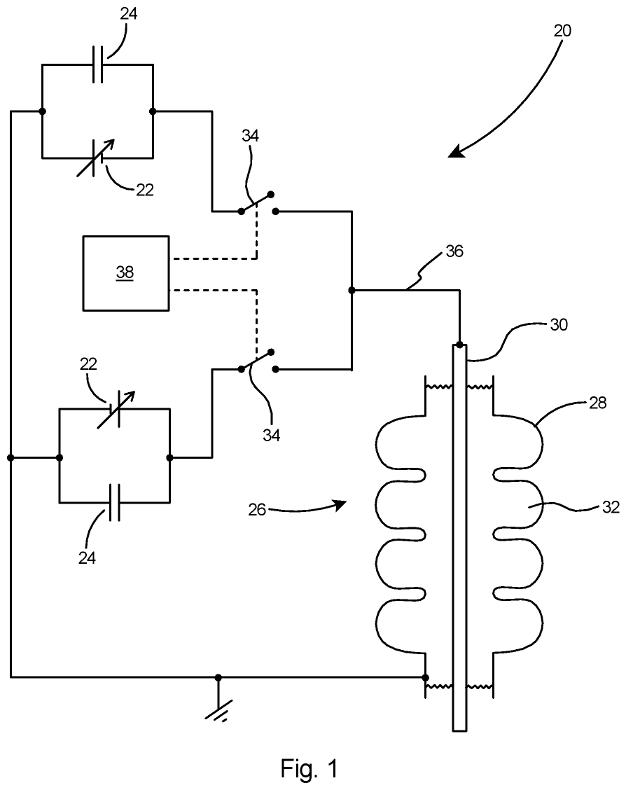

With reference to FIG. 1, the invention is a high current bi-polar pulse system 20 for use in electrochemical metal surface finishing. The high isolation, high current switching device provides a low-cost solution for implementing the surface finishing of niobium (Nb) SRF accelerating cavities without the use of hydrofluoric acid.

With reference to FIG. 1, the high current bi-polar pulse system 20 includes two or more independently settable high current DC power supplies 22, two or more high capacity capacitor banks 24, an electrochemical cell 26 including a metal finishing work piece 28, such as a niobium RF accelerator cavity, a counter electrode 30, and an electrically conducting fluid 32 (electrolyte) between the workpiece 28 and the counter electrode 30. Preferably, the DC power supplies 22 provide 4-20 volts (V) and the high capacity capacitor banks 24 preferably provide 10 farads (F) or greater electrical capacitance.

A switching device 34, preferably a fast switching, low impedance semi-conductor device 34, such as an insulated-gate bipolar transistor (IGBT), provides a high current, preferably greater than 500 amps (A), conduction path 36 from the capacitor banks 24 through the electrochemical cell 26. A timing control circuit 38 engages discharge of the capacitor banks 24 through the switching device 34 and electrochemical cell 26 according to a selected programmed sequence.

The net removal rate of oxides from the surface of the niobium structure is dependent upon the cathodic current density and the repetition frequency. Further, it is believed that the cathodic pulse duration affects the efficiency of the oxide removal at each pulse.

By way of example, one preferred embodiment of the system would generate a fifteen millisecond cathodic pulse, rest for five milliseconds, generate a ten millisecond anodic pulse, rest for five milliseconds, and then repeat the process until the desired effect has been achieved. The pulse duration may vary with the particular circumstances of use and the control scheme is sufficiently flexible to allow for such alteration and implementation.

The electrically conducting fluid 32 can be any suitably conductive fluid, even salt water. However, it will be recognized that fluids with high conductivity will increase the overall process rate, and, therefore, reduce the time necessary to polish a given surface area. A preferred embodiment of the invention would utilize sulfuric acid which possesses a sufficiently high level of conductivity to achieve the objects of the invention.

The high current bi-polar pulse system 20 is a high isolation, high current switching device that provides independently controllable, alternating polarity, variable time duration pulses for electrochemical and mechanical finishing of metallic components in an electrically conducting fluid bath. The system provides a safe, low-cost option for implementing surface finishing of metals in the metal industry and, more specifically, surface finishing of Nb SRF accelerating cavities without the use of hydrofluoric acid. The high current bi-polar pulse system 20 facilitates the economical and high quality surface finishing of Nb SRF accelerating cavities without the use of hydrofluoric acid. The invention has applicability to all types of particle accelerators employing bulk niobium SRF resonant structures, including cavity processing for the proposed International Linear Collider (ILC) for colliding electrons with positrons.

The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. An apparatus for electropolishing a superconductive radio frequency cavity comprising:
a cathodic voltage source comprising a first variable direct current power supply and a first capacitor bank in electrical communication with said first variable power supply;
an anodic voltage source comprising a second variable direct current power supply and a second capacitor bank in electrical communication with said second variable power supply;
a counter-electrode at least partially disposed in an electrolytic fluid which is in contact with a niobium cavity to be polished;
a first conductive path between said cathodic voltage source and said counter electrode;
a second conductive path between said anodic voltage source and said counter electrode;
a cathodic voltage switch positioned within the conductive path between said cathodic voltage source and said counter-electrode;
an anodic voltage switch positioned within the conductive path between said anodic voltage source and said counter-electrode; and,
a timing control circuit disposed to control the operation of said voltage switches.

2. The apparatus for electropolishing a superconductive radio frequency cavity of claim 1 wherein each of said first and second variable direct current power supplies is independently adjustable.

3. The apparatus for electropolishing a superconductive radio frequency cavity of claim 2 wherein each of said first and second variable direct current supplies is a high current power source and supplies between four and twenty volts.

4. The apparatus for electropolishing a superconductive radio frequency cavity of claim 3 wherein each of said first and second variable direct current supplies provides twenty volts.

5. The apparatus for electropolishing a superconductive radio frequency cavity of claim 1 wherein said apparatus does not include a rectifier.

6. The apparatus for electropolishing a superconductive radio frequency cavity of claim 1 wherein each of said first and second capacitor banks provides ten farads or greater electrical capacitance.

7. The apparatus for electropolishing a superconductive radio frequency cavity of claim 1 wherein each of said switching device is a fast switching, low impedance semi-conductor device.

8. The apparatus for electropolishing a superconductive radio frequency cavity of claim 7 wherein each of said switching devices is an insulated-gate bi-polar transistor.

9. An apparatus for electropolishing a superconductive radio frequency cavity comprising:
at least two direct current power supplies;
at least two capacitor banks; each capacitor bank connected to a separate direct current power supply;
a counter electrode connected to said capacitors via a conduction pathway; said counter electrode being in communication with an electrolytic fluid and said fluid being in contact with a surface of niobium cavity;
at least two switching devices positioned to regulate the conduction pathway between said capacitors and said counter electrode; and,
a timing control circuit disposed to operate said at least two switching devices.

10. A method of chemically processing a metallic work piece comprising the steps of:
providing a source of cathodic voltage comprising a first direct current power supply and at least one first capacitor providing at least ten farads electrical capacitance and a source of anodic voltage comprising a second direct current power supply and at least one second capacitor providing at least ten farads electrical capacitance;
connecting said sources of cathodic voltage and anodic voltage via a respective conduction path to an electrochemical cell comprising a metallic work piece, a counter electrode, and an electrically conducting fluid; and,
using a timing control circuit to alternate discharge of said at least one first capacitor and said at least one second capacitor according to a predetermined programmed sequence.

11. The method of claim 10 wherein each said conduction path incorporates an electronic switch.

12. The method of claim 11 wherein each said electronic switch further comprises an insulated-gate bipolar transistor.

13. The method of claim 12 wherein said insulated-gate bipolar transistors provide an at least five hundred amperes conduction path from said sources of cathodic voltage and anodic voltage through the electrochemical cell.

14. The method of claim 10 further comprising independently adjusting the output of each of said first and second power supplies in order to assist in generating the desired cathodic voltage and anodic voltage in the system.
